(19) United States
(12) Patent Application Publication
(10) Pub. No.: US 2026/0215313 A1
(43) Pub. Date: Jul. 23, 2026

(54) WIRE POST BUMP FORMING PROCESS

(71) Applicant: TEXAS INSTRUMENTS INCORPORATED, DALLAS, TX (US)

(72) Inventors: YOU CHYE HOW, MELAKA (MY); WEI LI JULIEN MOK, MELAKA (MY); HUAY YANN TAY, MELAKA (MY)

(21) Appl. No.: 19/033,890

(22) Filed: Jan. 22, 2025

(51) Int. Cl. H01L 23/00; H01L 21/56; H01L 21/78

(52) U.S. Cl. CPC H10W 72/015; H10W 72/075; H10W 72/50; H10P 54/00; H10W 72/01504; H10W 72/01561; H10W 72/07536; H10W 72/521; H10W 72/534; H10W 72/5434; H10W 72/5525; H10W 74/012; H10W 74/15; H10W 90/754; H10W 90/756

(57) ABSTRACT

A semiconductor device can include a supporting structure and a die that can include a surface on which wire posts can be located and coupled to die connection points. The wire posts can be coupled using solder to the supporting structure. For example, the wire posts can be formed on a wafer using a wire, which can be cut to provide the die. First and second end portions of the wire can be bonded to the wafer. A resist layer can be formed on a surface of the wafer to cover each of the first and second end portions while leaving a middle portion of the wire exposed. The middle portion of the wire can be grinded to leave the first and second wire portions of the wire embedded within the resist layer to form wire posts. The resist layer can be removed to reveal the wire posts.

### TECHNICAL FIELD

This disclosure relates to semiconductor packaging. More particularly, this disclosure relates to a wire post bump forming process.

### BACKGROUND

A semiconductor device is an electronic component made from semiconductor material with controlled electrical conductivity. The term “semiconductor device” can refer to various types of electronics, including individual components, such as diodes, transistors, photonic devices and power devices, as well as integrated circuits (IC). An IC can incorporate multiple electronic components and/or circuits into a single chip. A chip, also known as a microchip, silicon chip, or die, is a piece of semiconductor material, usually silicon, on which the IC is fabricated. ICs are built on a wafer and once complete, the wafer is cut to provide individual dies. The die can be mounted on a package substrate or a lead frame and encapsulated in a molding, such as a plastic to form an IC package or semiconductor package. The IC package is designed to be mounted on a printed circuit board (PCB) and connected to other components in an electronic system.

### SUMMARY

A first example relates to a semiconductor package that includes a supporting structure and a die. The die can include on a surface on wire posts and that can be coupled to die connection points of the die. The wire posts can be coupled using solder to the supporting structure.

A second examples relates to a method for forming wire posts that can include bonding first and second end portions of a wire to a wafer, forming a resist layer on a surface of the wafer to cover each of the first and second end portions while leaving a middle portion of the wire exposed, grinding the middle portion of the wire to leave the first and second wire portions of the wire embedded within the resist layer to form the wire posts, and removing the resist layer to reveal the wire posts.

A third example relates to a method for fabricating a semiconductor package. The method can include forming wire posts on a surface of a wafer. The wire posts can extend from a surface of the wafer. The method further includes cutting the wafer into dies. The wire posts can be formed on a die of the dies. The method further includes positioning the die with respect to a lead frame so that each wire post of the wire posts on the die is coaxial with a respective lead of the lead frame, reflowing solder to bond each wire post with the respective lead of the lead frame, and forming the semiconductor package by encapsulating the die and a portion of the lead frame with a molding material.

### BRIEF DESCRIPTION OF THE DRAWINGS

FIG. 1A illustrates a diagram of an example of a semiconductor device with wire posts.

FIG. 1B illustrates a diagram of another example of a semiconductor device with wire posts.

FIG. 2 illustrates a first stage of a method for forming a semiconductor device.

FIG. 3 illustrates a second stage of the method for forming the semiconductor package.

FIG. 4 illustrates a third stage of the method for forming the semiconductor package.

FIG. 5 illustrates a fourth stage of the method for forming the semiconductor package.

FIG. 6 illustrates a fifth stage of the method for forming the semiconductor package.

FIG. 7 illustrates a sixth stage of the method for forming the semiconductor package.

FIG. 8 illustrates a seventh of the method for forming the semiconductor package.

FIG. 9 illustrates an eighth stage of the method for forming the semiconductor package.

FIG. 10 illustrates a ninth stage of the method for forming the semiconductor package.

FIG. 11 illustrates a tenth stage of the method for forming the semiconductor package.

FIG. 12 illustrates an eleventh stage of the method for forming the semiconductor package.

FIG. 13 illustrates a twelfth stage of the method for forming the semiconductor package.

FIG. 14 illustrates a flowchart of an example method for forming one or more semiconductor devices according to the examples herein.

FIG. 15 illustrates an example of a wire bond profile.

FIG. 16 illustrates another example of a wire bond profile.

### DETAILED DESCRIPTION

This description relates to a bump forming process for use in semiconductor packaging. During wafer back-end processing, bumps are formed on a wafer. The bumps function as electrical and mechanical connections for a die and a supporting structure (e.g., a substrate or a lead frame). The bumps are created on the wafer while the wafer is intact (e.g., has not been cut into individual dies). Bumps are raised structures made of conductive materials (e.g., Copper) that are created on a surface of the wafer. In some instances, the bumps are Copper (Cu) pillars (referred to herein for simplicity as pillars). A pillar is a vertical structure made of Copper that extends upward from the surface of the wafer.

For example, during the wafer back-end process, a bump forming process can be executed to form the pillars on the wafer. The pillars can be formed at connection points on the wafer. Connection points are designated contact areas on the wafer on which interconnect structures, such as pillars can be created. The connection points are metalized areas (e.g., made of Copper or Aluminum) that provide a conductive surface on which the pillars can be formed during the bump forming process.

The bump forming process can begin with a deposition (e.g., sputtering) of a seed layer over the wafer. This seed layer is a thin metal layer that functions as a base for subsequent electroplating of the pillars. The seed layer can be formed by sputtering a seed material on the surface of the wafer.

After sputtering, a photoresist (PR) material is applied to the wafer to form a PR layer over the seed layer. The PR layer (or material) functions as a protective layer. In response to forming the PR layer, the wafer can be exposed to an ultraviolet (UV) light using a photomask. The photomask identifies areas on the wafer where the pillars will be formed. The photomask allows the UV light to pass through specific regions to expose an underlying PR material in these areas, which can be referred to as exposed PR areas (or regions) on the wafer. After the PR material is applied and the PR layer is selectively exposed using UV light, the exposed PR areas can be developed to dissolve the PR material in the exposed PR areas to reveal an underlying seed layer in these regions, which can be referred to as seed layer regions on the wafer.

For example, the wafer can be submerged in a developer solution to remove the PR material from the exposed PR areas to reveal the seed layer regions underneath. Areas on the wafer where the PR material is removed correspond to the locations on the wafer where Copper pillars can be grown and areas where the PR material was not removed correspond to areas on the wafer where no plating will occur. Thus, after development, openings are formed in the PR layer for plating. Thus, after PR coating, exposing, and developing, openings can be formed in the PR layer to expose the underlying seed layer regions on which Copper can be plated.

In exposed areas where PR was removed, Copper is then deposited into the openings on the seed layer regions using electroplating. The seed layer regions serve as a base on which Copper can accumulate or be deposited (plated). Copper is plated onto the seed layer regions to form an initial thin metal layer of the Cu pillar. A remaining PR material that was left on the surface of the wafer is removed (stripped away) to expose the seed layer in areas where Copper was not plated in response to Copper plating. A sequence of PR coating/exposure/developing, Copper plating, PR stripping and seed layer etching can be referred to as a pillar layering cycle. The pillar layering cycle can be repeated a number of times to build (e.g., grow) additional thin metal layers on the initial thin metal layer to achieve a desired (specified) pillar height and profile. Once the pillars have reached a desired pillar height (after a final or last pillar layering cycle), a PR material on the wafer after that pillar layering cycle round is stripped away to expose an underlying seed layer in areas that were protected during electroplating. The exposed seed layer around the pillars is etched away, leaving behind the pillars.

Following the bump forming process, wafer taping is performed to place a protective tape over the wafer to hold the wafer in position and protect the wafer for subsequent back-end processing. For example, the wafer can undergo back grinding, where a back side of the wafer can be grinded down to reduce a wafer thickness to prepare the wafer for further processing and assembly. After back grinding, wafer mounting can be performed using a dicing tape to prepare the wafer for sawing. The wafer is then cut into individual dies, which contain a subset of pillars of the pillars that have been formed using the bump forming process. Once the wafer is separated into individual dies, each die can be prepared for packaging device assembly.

The bump forming process requires multiple iterations of the pillar layering cycle to form Cu pillars on the wafer. This process is therefore time-intensive and involves significant material costs. Furthermore, each pillar layering cycle iteration needs precise control (e.g., deposition, plating and etching steps), which adds complexity to the bump forming process. In cases where taller or more complex pillars are needed, the pillar layering cycle needs to be repeated multiple times, which substantially increases an amount of time needed to form bumps on the wafer. Additionally, because the bump forming process is implemented at a wafer level (e.g., prior to the wafer being diced/cut), any inefficiencies or added complexities increase an overall production cost per wafer, and subsequently, a per-unit production cost (or package cost) of each chip.

According to one or more examples described herein, a wire bump forming process is described for forming wire-based interconnect structures. The wire-based interconnect structures can include wire posts. The wire posts can be conductive elements that can be used to form an electrical and mechanical connection between one or more dies and a supporting structure (e.g., a substrate or a lead frame). The wire bump forming process is a simplified alternative to an existing bump (or Cu pillar) forming process and replaces Cu pillar formation with wire bonding formation. The bump forming process involves multiple iterations of a bump pillar layering cycle (e.g., several steps, such as PR coating/exposure/developing, Copper plating, PR stripping and seed layer etching) to form interconnect structures (Cu pillars) on a wafer.

By using portions of the wire as the interconnect structures, which are referred to herein as wire posts, the wire bump forming reduces a manufacturing cost of forming bumps on a wafer and thereby semiconductor device costs. For example, by using the wire bumping forming process rather than the existing bump forming process to form the bumps on the wafer, reduces a number of manufacturing steps and materials needed for bump formation. Additionally, the use of wire posts as interconnect structures does not create bonding problems during reflow as the wire posts exhibit a similar or same wettability as Cu pillars with solder. Moreover, by using the wire bump forming process, as described herein, eliminates a need for complex steps such as wafer taping for grinding a back of a wafer, which not only reduces material costs but also shortens an overall time needed for bump formation.

Furthermore, the use of wire posts as interconnect structures for connecting the one or more dies to the support structure (compared to Cu pillars) allows for greater current to be carried by the interconnect structures. For example, in some instances, the wire posts can be formed from thick wires or ribbon wires. In yet some instances, multiple wire posts can be formed on the wafer as the interconnect structure for coupling the die to the support structure. By using multiple wire posts as the interconnect structure increases a total cross-sectional area of the interconnect structure (e.g., when compared to a single wire post functioning as the interconnect structure) is increased, effectively lowering a resistance between the die and the support structure, thereby increasing an overall current capacity between the die and the support structure (e.g., when compared to examples in which the interconnect structure is the Cu pillar).

Using thicker wires (e.g., thicker round wires) for interconnect structure formation curtails an electrical resistance between the die and the support structure, as thicker conductors can carry more current without generating excessive heat. Thicker wire posts have a larger cross-sectional area, which decreases resistance and improves a current carrying capacity of a wire post. Cu pillars are often constrained by fixed dimensions, such as height and cross-sectional area, which limits an amount of current such interconnect structures can carry between the die and the structure. However, using wires for interconnect structure formation allows for the formation of thicker or wider wire posts. In some examples, ribbon bonding can be used, where a flat, ribbon-like wire is bonded to the wafer for forming a ribbon wire post. A ribbon wire is a single, continuous wire that is flat and ribbon-like in shape. A cross-section of the ribbon wire post is rectangular or oval when compared to a circular cross-section of a round wire post. Ribbon wire posts have a greater cross-sectional area when compared to round wire posts or Cu pillars of a same height, which allows for more current to flow through such interconnect structures. An increased surface area of ribbon wire posts makes ribbon wire posts preferable for high-current applications (e.g., compared to Cu pillars).

For example, during the wire bump forming process, a metal wire (such as a Copper wire) can be attached (bonded) to connection points on the wafer in a process known as wire bonding. The wire bonding can include a ball bonding process and/or a stitching bonding process (in some instances known as wedge bonding).

In some examples, during the ball bonding process, a wire bonder can form a molten ball (e.g., of Copper or Gold) at an end of a wire. The wire bonder can be used to press the molten ball against a first connection point on the wafer, where the molten ball solidifies and welds, forming a ball bond at the first connection point. The wire bonder can be used for implementing a sequential bonding sequence. During the sequential bonding sequence, such as in a first example, the wire bonder is configured to pull the wire to a second connection point on the wafer, in some instances, for a stitch bond. The wire bonder can press the wire to the surface and weld the wire without creating another molten ball, leaving a flattened, welded spot at the second connection on the wafer. After attaching the wire to the second connection point on the wafer, the wire bonder can pull the wire to a third connection point on the wafer. In the first example, the wire bonder can be used to sequentially pull and bond the wire to additional connection points on the wafer, using stitch bonds to create flattened, welded spots at each point.

In some examples, during the stitch bonding process, a wire bonder can press down the wire at the first connection point to create a stitch bond or wedge bond, which can resemble a flattened weld. After making the stitch bond, the wire bonder can pull the wire to the next connection point (the second connection point). Once there, the wire bonder can be configured to weld the wire to the second connection point. The wire bonder can be used to sequentially pull and bond the wire to additional connection points on the wafer, using stitch bonds to create flattened, welded spots at each point.

In some examples, during the sequential bonding sequence, such as in a second example, the wire bonder is configured to break (or snap) the wire after forming the ball bond at the first connection point. In the second example, a molten ball can be formed at an end of a wire. The wire bonder can be used to press the molten ball against the second connection point on the wafer, where the molten ball solidifies and welds, forming a ball bond at the second connection point. In the second example, the wire bonder is configured to break the wire after forming the ball bond at the second connection point. In the second example, the wire bonder can be used to sequentially form individual ball bonds at each subsequent connection point on the wafer, breaking the wire after each ball bond to create individual ball bonds at each point. Each individual ball bond created at each connection point can be referred to as a wire post once the wire has been broken off. These individual ball bonds (wire posts) are vertical conductive structures that can function as interconnect structures on the wafer.

Wire posts formed using ball bonds can be substantially vertical with respect to a surface of the wafer (referred to herein as a wafer surface). The ball bonding process can be used to form vertical structures when the wire is broken off at each connection point on the wafer. The molten ball solidifies at a connection point, forming a spherical or slightly flattened shape, which can result in a vertical alignment with respect to the wafer surface. By contrast, stitch bonds, or wedge bonds, can result in a slanted wire angle and thus the wire posts can be angled (or slanted) with respect to the wafer surface. When the wire is pulled from one connection point to another on the wafer, the bonding process creates a flattened weld rather than a spherical shape, and the wire often departs from the connection point at an angle. Stitch bonds result in a wire post being formed that departs from the connection point at an angle relative to the wafer surface.

For example, a first portion of the wire is bonded to the first connection point on the wafer and the second portion of the wire is bonded to the second connection point on the wafer to form a wire bond between the first and second connection points on the wafer. Connection points are metalized areas located on a surface of the wafer for circuit regions, which will become individual dies after the wafer is sliced (cut). These connection points can be designed for transferring power, signals, and providing a ground connection for a circuit (e.g., an IC) to other parts of the semiconductor package, such as the support structure (e.g., a substrate or lead frame). Wire bonds can be formed across the wafer to join multiple connection points using the wire. A number of wire bonds formed on the wafer can be based on the number of connection points on the wafer or some subset thereof.

After wire bonding is complete, a PR material can be applied (coated) over the wafer to form a PR layer over a surface of the wafer. The PR layer also coats a portion of the wire bonds (the first and second portions of the wire), which can be referred to as a lower wire portion. The PR layer protects the lower wire portion of each wire bond while leaving an upper wire portion of the wire exposed (e.g., uncoated). The upper wire portion can be above a surface of the PR layer and can be referred to as an exposed upper wire portion. The thickness of the PR layer can define a height of the lower wire portion of each bonded wire. The PR layer functions as a protective layer to prevent lower wire portions of the bonded wires from being damaged during subsequent steps of the wire bump forming process, as described herein.

In some examples, during the wire bump forming process, the wafer undergoes a grinding step to remove the exposed upper wire portion of each bonded wire. For example, each exposed upper wire portion can be gradually removed through grinding. The grinding continues until a top portion (or surface) of the hardened PR layer is reached, which functions as a boundary to prevent further grinding of the bonded wire. Thus, once each exposed upper wire portion is grinded (e.g., removed), lower wire portions of the wire remain in the PR layer. Each lower wire portion embedded in the PR layer can be orientated vertically or about vertically in the PR layer with respect to wafer surface and can be referred to as a wire post. Each wire post is an interconnect structure that functions as an electrical and mechanical interface in subsequent packaging steps. Wire posts provide a same functionality as traditional pillars (Cu pillars), allowing for a connection between a die and supporting structure to be made.

After grinding, the PR layer that was used to protect the lower wire portions of the bonded wires can be removed. For example, a PR stripping process can be applied to the wafer, which can include applying a chemical PR stripper or using plasma etching to remove the PR layer. Once the PR layer has been removed from the surface of the wafer, remaining lower wire portions of the bonded wires corresponding to the wire posts are exposed. In response to removing the PR layer, for example, using the PR stripping process, the wafer can be referred to as a bumped wafer.

In some examples, in response to (or after) the wire bump forming process, the bumped wafer can be cut (sawed) into individual dies and one or more dies can be packaged using a semiconductor packaging technology, such as flip-chip packaging. Each die can include a subset of wire posts of the wire posts that had been formed using the wire bump forming process.

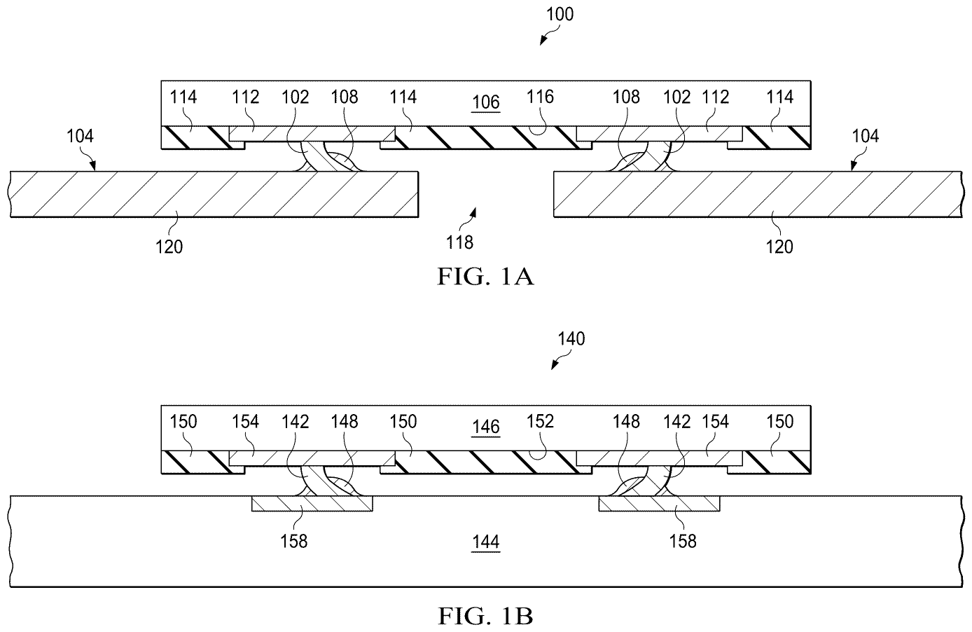

FIG. 1A illustrates a diagram of an example of a semiconductor device 100 with wire posts 102. The semiconductor device 100 includes a support structure, such as a lead frame 104, and a die 106. The lead frame 104 can hold the die 106. The die 106 and a portion of the lead frame 104 can be packaged to provide the semiconductor device 100, such as according to one or more examples herein.

For example, the die 106 and the lead frame 104 can be packaged using a packaging technology, such as flip-chip packaging, which can include using a bonding material 108 to form electrical and mechanical connections between the lead frame 104 and the die 106. In some examples, the bonding material 108 is a solder (or solder paste). The term “solder” refers to an alloy (e.g., in some instances a combination of tin and lead or lead-free alloys) that can be used for joining components in electronics/circuits. In some instances, the bonding material 108 are solder bumps. Solder bumps are spherical metallic connectors. In yet further examples, the bonding material 108 are solder bars. Solder bars differ in shape and volume from solder bumps. Rather than being small, spherical connectors, solder bars are elongated, long oval-shaped structures, designed to distribute mechanical stress more evenly across the die 106 and the lead frame 104. In some examples, the semiconductor device 100 includes a passivation (PO) layer 114 on a surface 116 of the die 106 around die connection points 112. The PO layer 114 can function as a protective layer to protect underlying components/layers of the die 106.

The wire posts 102 can extend from the die connection points 112 (or metal contacts) of the die 106 toward the lead frame 104, as shown in FIG. 1A. The die connection points 112 can be located on the surface 116 (or a face) of the die 106. The die connection points 112 can be formed in some instances in a top layer of the die 106. Each of the wire posts 102 of the die 106 is bonded to the lead frame 104 by the bonding material 108. The lead frame 104 includes leads 120 a portion of each extending under a surface of die 106 and a space 118 between inner ends of opposing ones of the leads 120. In yet some examples, the leads 120 (also known as lead fingers or conductive elements) are made of Copper or copper alloys. The wire posts 102 on the die 106 contact corresponding ends of the leads 120, as shown in FIG. 1A to couple the die 106 to the lead frame 104.

The wire posts 102 can project about vertically with respect to the surface 116 of the die 106. The wire posts 102 are interconnect structures that are used to provide a mechanical and electrical connection between the lead frame 104 and the die 106. In some examples, the wire posts 102 are round wire posts. In yet some examples, the wire posts 102 are ribbon wire posts, which provide a greater (e.g., larger) cross-sectional area when compared to a round wire post. A shape of a ribbon wire post can be flat and wide and can provide more surface area for current to pass through than a round wire post of a same or similar height while generating less heat when compared to the round wire post. Ribbon wire posts can be used as the wire posts 102 of the semiconductor device 100 in higher-power applications.

In yet some examples, each of the wire posts 102 can correspond to multiple wire posts, having respective ends bonded to a same (or similar) contact point (e.g., one of the die connection points 112). This configuration can be achieved by bonding multiple individual wire portions at slightly different angles or positions with respect to a contact point so that these wire posts make electrical contact with a same metal pad without overlapping or interfering with each other. Use of multiple wire posts increases a total cross-sectional area of an interconnect between the lead frame 104 and the die 106 and thus an amount of current that can be carried between the lead frame 104 and the die 106.

FIG. 1B illustrates a diagram of another example of a semiconductor device 140 with wire posts 142. The wire posts 142 can correspond to the wire posts 102 of FIG. 1A. The semiconductor device 140 includes a support structure, such as a substrate 144, and a die 146. In some examples, the die 146 can correspond to the die 106 of FIG. 1A. The substrate 144 can be an embedded trace substrate (ETS), in some examples. The substrate 144 can support the die 146. The die 146 and the substrate 144 can be packaged to provide the semiconductor device 140 according to one or more examples herein.

For example, the die 146 and the substrate 144 can be packaged using a packaging technology, such as flip-chip packaging, which can include using a bonding material 148 to form electrical and mechanical connections between the substrate 144 and the die 146. In some examples, the bonding material 148 is a solder (or solder paste). In yet some examples, the bonding material 148 are solder bumps or solder bars. In some examples, the semiconductor device 140 includes a PO layer 150 that can be formed on a surface 152 of the die 146 around die connection points 154. The PO layer 150 can function as a protective layer to protect underlying components/layers of the die 146.

The wire posts 142 can extend from the die connection points 154 (or metal contacts) of the die 146 toward the substrate 144, as shown in FIG. 1B. The die connection points 154 can be located on the surface 152 (or a face) of the die 146. The die connection points 154 can be formed, in some instances, in a top layer of the die 146. Each of the wire posts 142 of the die 146 is bonded to a respective substrate pad of the substrate pads 158 of the substrate 144. The wire posts 142 on the die 146 can make contact via the bonding material 148 (the solder) with a corresponding substrate pad 158, as shown in FIG. 1B to couple the die 146 to the substrate 144.

The wire posts 142 can project about vertically with respect to the surface 152 of the die 146. The wire posts 142 are interconnect structures that are used to provide a mechanical and electrical connection between the substrate 144 and the die 146. In some examples, the wire posts 142 are round wire posts. In yet some examples, the wire posts 142 are ribbon wire posts, which provide a greater (e.g., larger) cross-sectional area compared to a round wire post. A shape of a ribbon wire post can be flat and wide and can provide more surface area for current to pass through than a round wire post of a same or similar height while generating less heat when compared to the round wire post. Ribbon wire posts can be used as the wire posts 142 of the semiconductor device 140 in higher-power applications.

In other examples, each of the wire posts 142 can correspond to multiple wire posts, having respective ends bonded to a same contact point (e.g., one of the die connection points 154). This configuration can be achieved by bonding multiple individual wire portions at slightly different angles or positions with respect to a contact point so that these wire posts make electrical contact with a same metal pad without overlapping or interfering with each other. Use of multiple wire posts increases a total cross-sectional area of an interconnect between the substrate 144 and the die 146 and thus an amount of current that can be carried between the substrate 144 and the die 146.

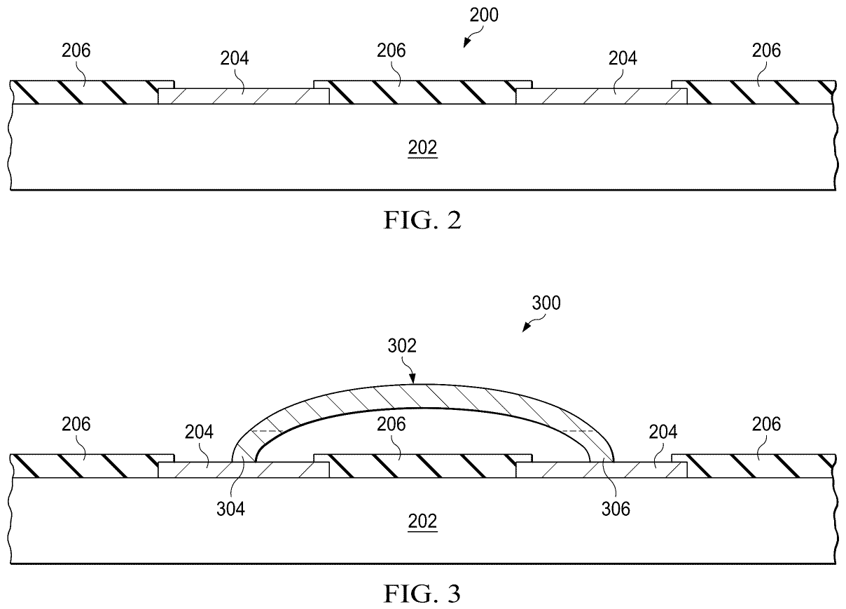

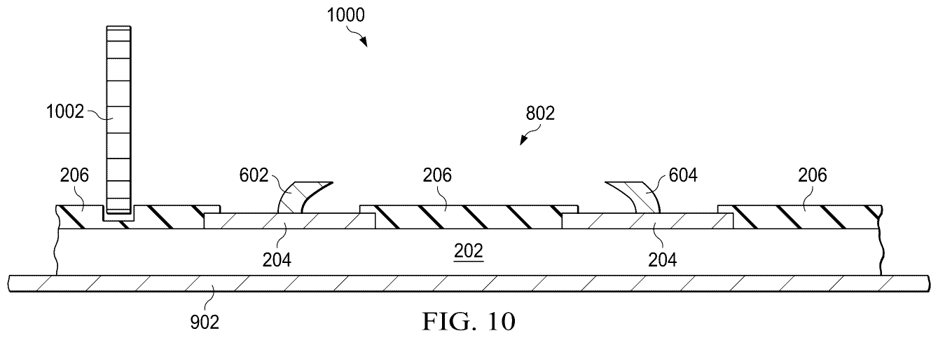

FIGS. 2-13 illustrate stages of a method for fabricating (e.g., assembling) a semiconductor package, such as the semiconductor device 100, as shown in FIG. 1A. As illustrated in FIG. 2, at 200, in a first stage, a wafer 202 is prepared (produced). In some examples, at the first stage 200, the wafer 202 can be provided (or received). The wafer 202 can be provided with connection points 204 that are to be used as die connection points (e.g., the die connection points 112 of FIG. 1A). The connection points 204 can be metal contact areas that are located on a surface of the wafer 202 (or in a top layer of the wafer 202). The connection points 204 correspond to electrical connection points, on which wire posts can be formed according to one or more examples herein. The connection points 204 can be coupled to underlying circuitry formed in the wafer 202, such as metallization layers that provide electrical pathways to transistors and/or other active components fabricated in the wafer 202. The connection points 204 can connect to external components like a lead frame (e.g., the lead frame 104 of FIG. 1A) once the wafer 202 is diced into individual dies, which can include the die 106 of FIG. 1A. A PO layer 206 (e.g., the PO layer 114 of FIG. 1A) is also present on the surface of the wafer 202, surrounding the connection points 204, to protect an underlying circuitry and structure of the wafer 202 while leaving the connection points 204 exposed for subsequent processes, as described herein.

At a second stage, at 300, as illustrated in FIG. 3, a metal wire 302 (e.g., a Cu wire) is attached (bonded) to the connection points 204 on the wafer 202. For example, during a wire bump forming process, the metal wire 302 can be attached (bonded) to the connection points 204 on the wafer 202 in a process known as wire bonding, as described herein. The wire bonding process can include a stitching bonding process (in some instances known as wedge bonding) to sequentially attach the metal wire to multiple connection points to form bonded wires. In some instances, a wire bonder can be used to attach the metal wire 302 to the wafer 202 by forming a series of stitch bonds to form wire bonds between connection points, such as the connection points 204 of the wafer.

For example, a first end portion 304 of the metal wire 302 can be bonded to a first wafer connection point (one of the connection points 204) using a stitch bond and a second end portion 306 of the metal wire 302 can be bonded using another stitch bond to a second connection point (e.g., another connection point of the connection points 204) on the wafer 202. Once the first and second end wire portions 304-306 of the metal wire 302 are bonded to the wafer 202 this forms a wire bond between the connection points 204. The wire bonder can be used to form a number of wire bonds between connection points of the wafer 202 by sequentially bonding wire portions of the metal wire 302 to other connection points on the wafer, until specified (or identified) connection points of the wafer 202 are covered. In scenarios where the wafer 202 has an odd number of connection points, wire bonding can be performed by bonding a wire to another connection point that already has a wire bond, thus allowing for multiple connections at a same connection point (e.g., one of the connection points 204).

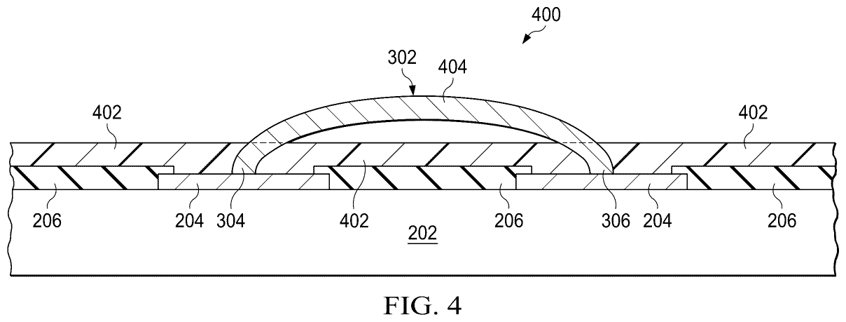

At a third stage, at 400, as illustrated in FIG. 4, a resist layer 402 can be formed on the surface of the wafer 202 to cover each of the first and second end portions 304-306 of the metal wire 302 while leaving a middle portion 404 of the metal wire 302 exposed. In some examples, the resist layer 402 is a PR layer. The resist layer 402 can be a positive PR layer. In some examples, at 400, the surface of the wafer 202 is coated with a resist material (e.g., PR material) to form the resist layer 402 on the surface of the wafer 202 while leaving the middle portion 404 of the metal wire 302 exposed (e.g., not-coated).

The middle portion 404 of the metal wire 302 is positioned above the resist layer 402, as the resist material is applied to the surface of the wafer 202, covering the first and second end portions 304-306 that are bonded to the wafer 202. Since the metal wire 302 extends between two contact points (e.g., the connection points 204), the middle portion 404 of the metal wire 302 can remain suspended above the resist layer 402, not contacting the wafer 202 or the resist layer 402. This floating-wire configuration is a result of a wire's geometry after bonding, where the metal wire 302 forms an arch or span between the two contact points, leaving the middle portion 404 of the metal wire 302 exposed for further processing according to one or more examples herein.

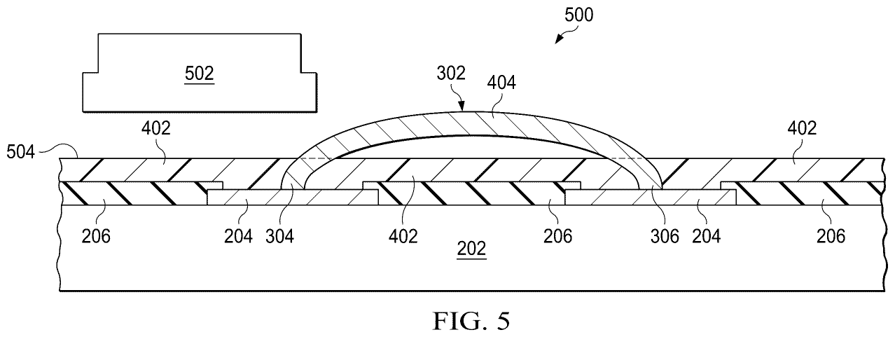

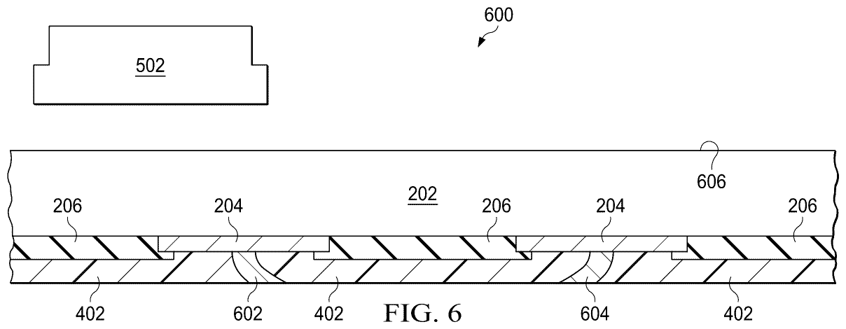

At a fourth stage, at 500, as illustrated in FIG. 5, the middle portion 404 of the metal wire 302 is grinded to leave the first and second portions 304-306 of the metal wire 302 embedded within the resist layer 402 to form wire posts 602-604, as shown in FIG. 6. The middle portion 404 of the metal wire 302 can be grinded with a grinding wheel 502 until a top surface 504 of the resist layer 402 is reached to form the wire posts 602-604. A height of the wire posts 602-604 is based on a thickness of the resist layer 402.

At a fifth stage, at 600, as illustrated in FIG. 6, a back-side 606 of the wafer 202 can be grinded to thin the wafer 202 to a desired wafer thickness (e.g., in some instances to about 10 thousandths of an inch, or 0.010 inches). For example, the back-side 606 of the wafer 202 (opposite a side on which the wire posts 602-604 are located) can be grinded using the grinding wheel 502. The wafer 202 can be thinned at the fifth stage to reduce an overall package size of dies (once the wafer 202 is sliced).

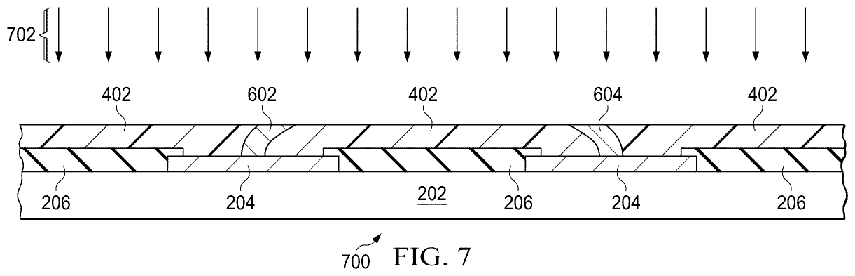

At a sixth stage, at 700, as illustrated in FIG. 7, the resist layer 402 can be exposed to a UV light 702. When the resist layer 402 is exposed to the UV light 702, the UV light 702 breaks down a chemical structure of the resist layer 402, making the resist layer 402 more soluble in a developer solution.

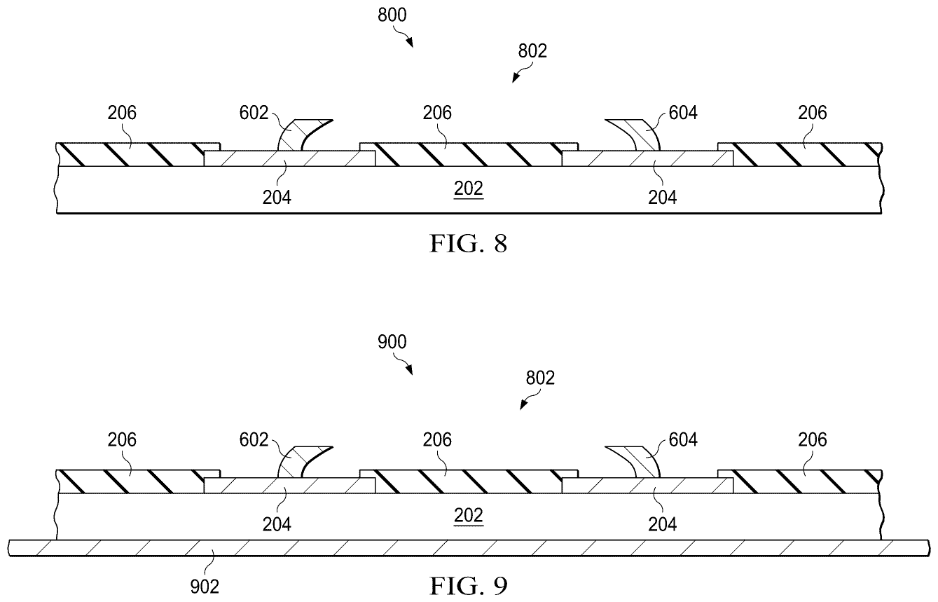

At a seventh stage, at 800, as illustrated in FIG. 8, the wafer 202 can undergo PR developing to remove the resist layer 402 to provide a wafer assembly 802 (e.g., a bumped wafer), as shown in FIG. 8. For example, the PR development can include immersing the wafer 202 in response to being exposed to the UV light 702 in the developer solution. Thus, at the seventh stage, at 800, the wafer 202 can undergo a chemical process to strip the resist layer 402 and thus undergo PR stripping.

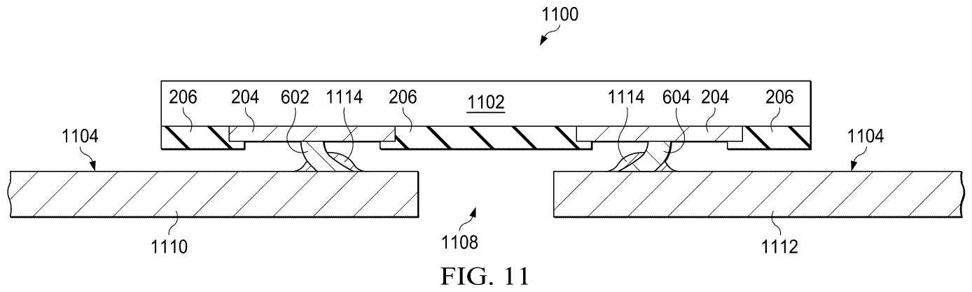

At an eighth stage, at 900, the wafer assembly 802 is mounted onto a dicing tape or mounting frame 902. A mounting process at 900 secures the wafer assembly 802 in place for a dicing stage. Once the wafer assembly 802 (and thus the wafer 202) is mounted, the wafer 202 can be diced into individual dies, which can then be processed further or packaged according to the design requirements. For example, at a ninth stage, at 1000, the wafer 202 is cut into individual dies, to provide a die 1102, as shown in FIG. 11. By way of example, the wafer 202 is cut using a saw blade 1002 into individual dies. The die 1102 can correspond to the die 106 of FIG. 1A.

At a tenth stage, at 1100, the die 1102 can be attached to a lead frame 1104 (e.g., the lead frame 104 of FIG. 1). For example, the lead frame 1104 includes leads 1110-1112 a portion of each extending under a surface of die 1102 and a space 1118 (e.g., the space 118 of FIG. 1A) between inner ends of opposing ones of the leads 1110-1112 (e.g., the leads 120 of FIG. 1A). The die 1102 can be attached to the lead frame 1104 using a flip-chip process, which can include using a reflow process. In the flip-chip process, the die 1102 is flipped upside down so that metal contacts (e.g., the connection points 204 of FIG. 1) are facing downward toward the lead frame 1104. This orientation allows electrical connections to be made between the connection points 204 of the die 1102 and the corresponding leads 1110-1112 of the lead frame 1104. For example, the die 1102 can be positioned with respect to the lead frame 1104 so that each wire post of the wire posts 602-604 on the die 1102 is coaxial with a respective lead of the leads 1110-1112 of the lead frame 1104.

In some examples, a bonding material 1114, such as solder bumps (or solder paste), is used to bond the wire posts 602-604 of the die 1102 to corresponding leads of the leads 1110-1112 of the lead frame 1104 to secure the die 1102 to the lead frame 1104. In some examples, the bonding material 1114 (e.g., the bonding material 108 of FIG. 1A) can be deposited on the leads 1110-1112 of the lead frame 1104. In yet other examples, the bonding material 1114 is deposited on the wire posts 602-604. In response to flipping and aligning the die 1102 with the lead frame 1104, a reflow process can be applied to such a semiconductor assembly. During reflow, the bonding material 1114 melts to form connections (e.g., mechanical and electrical connections) between the wire posts 602-604 and the leads 1110-1112. As the semiconductor assembly cools, the bonding material 1114 solidifies to attach the die 1102 to the lead frame 1104.

At an eleventh stage, at 1200, the die 1102 and a portion of the lead frame 1104 are encapsulated within a molding compound 1202 to form an assembly package 1204. After the molding compound 1202 is applied, the assembly package 1204 can be subjected to a post-mold curing process.

At a twelfth stage, at 1300, the assembly package 1204 can proceed to a trim and form stage to provide a semiconductor device 1302, which, in some instances, can correspond to the semiconductor package 100 of FIG. 1A. For example, during this stage, excess mold compound can be trimmed from the assembly package 1204 to create a clean, final package shape (e.g., the semiconductor device 1302). Additionally, the lead frame 1104 can be formed to create an appropriate lead shape for mounting on a printed circuit board (PCB) the semiconductor device 1302. The forming step can include bending and shaping the leads 1110-1112 of the lead frame 1104 into a final lead shape (or geometry) configuration to prepare the semiconductor device 1302 for use in an electronic system.

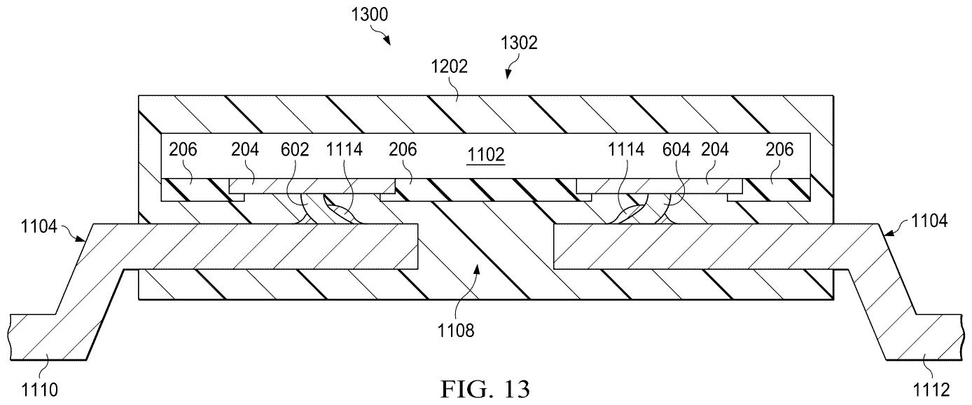

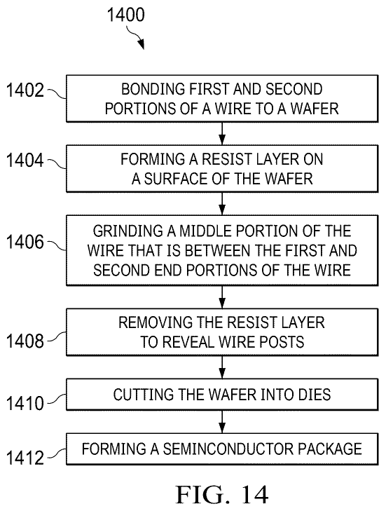

FIG. 14 illustrates a flowchart of an example method 1400 for forming a semiconductor device. The method 1400 could be employed, for example, to form the semiconductor device 100 of FIG. 1A, the semiconductor device 140 of FIG. 1B or the semiconductor device 1302 of FIG. 13.

The method can begin at 1402 with bonding first and second portions (e.g., the first and second end portions 304-306 of FIG. 3) of a wire (e.g., the metal wire 302 of FIG. 3) to a wafer (e.g., the wafer 202 of FIG. 1). At 1404, a resist layer (e.g., the resist layer 402 of FIG. 4) can be formed on a surface of the wafer to cover the first and second end portions while leaving a middle portion of the wire (e.g., the middle portion 404 of the metal wire 302 of FIG. 4) exposed. At 1406, the middle portion of the wire that is exposed can be grinded (e.g., using the grinding wheel 502 of FIG. 5) to the resist layer to leave the first and second wire portions of the wire embedded within the resist layer to form wire posts (e.g., the wire posts 602-604 of FIG. 6). At 1408, the resist layer is removed to reveal the wire posts.

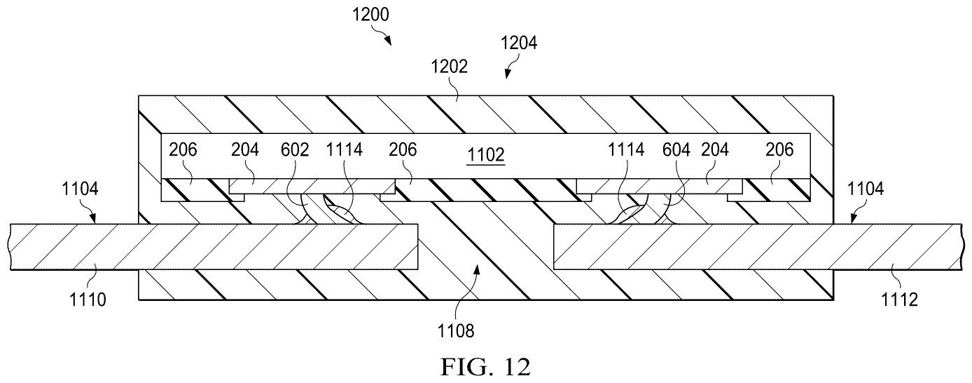

At 1410, the wafer is cut into dies. The wire posts can be located on a respective die (e.g., the die 106 of FIG. 1A, the die 146 of FIG. 1B or the die 1102 of FIG. 11) of the dies. At 1412, the semiconductor package is formed using a molding material, the respective die and a support structure for the respective die. In some instances, at 1412, the semiconductor package can be formed by encapsulating the respective die and a portion of a lead frame (e.g., the lead frame 104 of FIG. 1A or the lead frame 1104 of FIG. 11) with a molding material (e.g., the molding compound 1202 of FIG. 12). In yet other instances, at 1412, the semiconductor package can be formed by encapsulating the respective die and a substrate (e.g., the substrate 144 of FIG. 1B) with a molding material (e.g., the molding compound 1202 of FIG. 12).

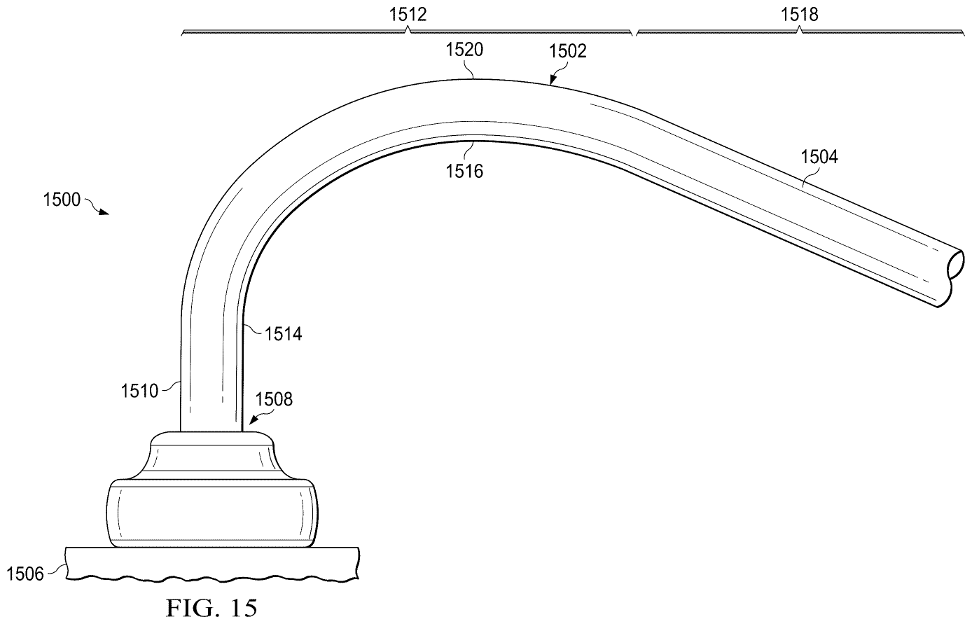

FIG. 15 illustrates an example of a wire bond profile 1500 for a wire bond 1502. For example, a wire bonding process as described herein (e.g., a ball bonding process) can be used to bond a first end 1508 of a wire 1504 (e.g., the wire 302 of FIG. 3) to a connection point 1506 (e.g., the connection point 204 of FIG. 3) on a wafer (e.g., the wafer 202 of FIG. 3) to provide the wire bond 1502. A second end of the wire 1504 can be bonded to a second connection point on the wafer according to one or more examples, as described herein. For example, during a ball bonding process, a molten ball can be formed at a tip (the first end 1508) of the wire 1504. The molten ball can be pressed onto the connection point 1506 on the wafer using a wire bonder, where the molten ball solidifies and forms a ball bond. After the ball bond is created, the wire bonder lifts the wire 1504 to form a wire neck 1510 and a wire loop portion 1512 of the wire bond 1502. The wire 1504 can be guided to the second connection point on the wafer, where the wire 1504 can be pressed down to create a bond. In some examples, the wire 1504 is broken off at the second connection point, completing the wire bond 1502 with a wire downward portion 1518 of the wire bond 1502 descending to the second bond location.

As shown in FIG. 15, the wire bond 1502 includes the wire neck 1510, the wire loop portion 1512 and the wire downward portion 1518. The wire neck 1510 of the wire 1504 extends from the connection point 1506 at a perpendicular angle (or substantially perpendicular angle) with respect to the connection point 1506 (or a surface of the wafer) and thus in some instances can be referred to as a vertical neck. In a non-limiting example, the wire neck 1510 can extend about 75 micrometers (μm) before transitioning to a bend. In some examples, a first kink 1514 or an initial bend can be located between the wire neck 1510 and the wire loop portion 1512. The first kink 1514 changes a direction of the wire 1504 from a vertical orientation toward an upward angle, forming a rising part of the wire loop portion 1512.

In some examples, the wire bond 1502 can reach a maximum height above the surface of the wafer, as identified at 1520 in FIG. 15, which can occur along the wire loop portion 1512 or at another elevated point depending on the wire bond profile 1500. In a non-limiting example, the maximum height that the wire bond 1502 is above the surface of the wafer can be about 190 μm. A bending angle at the first kink 1514 in a non-limiting example can be about 20 degrees with respect to the connection point 1506. The first kink 1514 can be a first bend were the wire 1504 transitions from the wire neck 1510 to the wire loop portion 1512. In some examples, a second kink 1516 or a subsequent bend can be located between the wire loop portion 1512 and the wire downward portion 1518. At the second kink 1516, the wire 1504 changes direction from the upward angle to a downward angle, descending toward the second connection point. The downward angle can align the wire 1504 to complete the bond at the second connection point on the wafer.

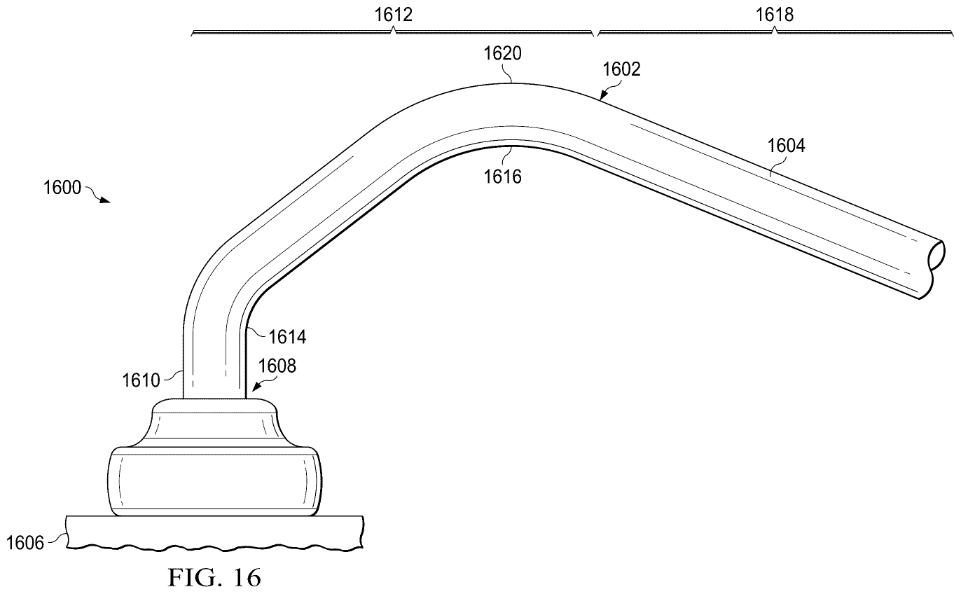

The wire bond profile 1500 can be used in standard packaging applications where wire bond height is not constrained. The wire bond profile 1500, as shown in FIG. 15, features an extended wire neck and a gradual first bend (e.g., when compared to a wire bond profile 1600 of FIG. 16), resulting in a taller wire loop portion. A taller wire loop portion can more effectively absorb mechanical and thermal stresses, distributing such stresses more evenly across the wire bond 1502 and reduces a risk of bond fractures or wire fatigue in applications where package height is not a limiting factor.

In contrast to the wire bond profile 1500, the wire bond profile 1600, shown in FIG. 16, represents a low loop wire bond designed for applications where package height is minimal (reduced). Thus, the wire bond profile 1600 has a shorter wire neck and a sharper initial bend, resulting in a lower wire loop when compared to the wire bond profile 1500 of FIG. 15. The reduced loop height enables a wire bond 1502 of the wire bond profile 1600 to fit within tight vertical constraints while maintaining reliable electrical and mechanical connections. In some instances, for flip-chip applications that involve forming wire posts, the wire bond profile 1500 can be used. Using wire bond profile 1500 during wire bonding helps ensure that after wire posts (the wire posts 602-604 of FIG. 6) are exposed, the wire posts remains straight and vertically aligned with respect to the surface of the wafer. This vertical alignment allows for consistent placement and reliable bonding to solder paste during a package formation process (or assembly process), which minimizes a risk of misalignment or connection issues.

FIG. 16 illustrates another example of a wire bond profile 1600 for a wire bond 1602. For example, a wire bonding process as described herein (e.g., a ball bonding process) can be used to bond a first end 1608 of a wire 1604 (e.g., the wire 302 of FIG. 3) to a connection point 1606 (e.g., the connection point 204 of FIG. 3) on a wafer (e.g., the wafer 202 of FIG. 3) to provide the wire bond 1602. A second end of the wire 1604 can be bonded to a second connection point on the wafer according to one or more examples, as described herein. For example, during a ball bonding process, a molten ball can be formed at a tip (the first end 1608) of the wire 1604. The molten ball can be pressed onto the connection point 1606 on the wafer using a wire bonder, where the molten ball solidifies and forms a ball bond. After the ball bond is created, the wire bonder lifts the wire 1604 to form a wire neck 1610 and a wire loop portion 1612 of the wire bond 1602. The wire 1604 can be guided to the second connection point on the wafer, where the wire 1604 can be pressed down to create a bond. In some examples, the wire 1604 is broken off cleanly at the second connection point, completing the wire bond 1602 with a wire downward portion 1618 of the wire bond 1602 descending to the second bond location.

As shown in FIG. 16, the wire bond 1602 includes the wire neck 1610, the wire loop portion 1612 and the wire downward portion 1618. The wire neck 1610 of the wire 1604 extends from the connection point 1606 at a perpendicular angle (or substantially perpendicular angle) with respect to the connection point 1606 (or a surface of the wafer) and thus in some instances can be referred to as a vertical neck. In a non-limiting example, the wire neck 1610 can extend about 33 μm before transitioning to a bend. In some examples, a first kink 1614 or an initial bend can be located between the wire neck 1610 and the wire loop portion 1612. The first kink 1614 changes a direction of the wire 1604 from a vertical orientation toward an upward angle, forming a rising part of the wire loop portion 1612.

In some examples, the wire bond 1602 can reach a maximum height above the surface of the wafer, as identified at 1620 in FIG. 16, which can occur along the wire loop portion 1612 or at another elevated point depending on the wire bond profile 1600. In a non-limiting example, the maximum height that the wire bond 1602 is above the surface of the wafer can be about 160 μm. A bending angle at the first kink 1614 in a non-limiting example can be about 40 degrees with respect to the connection point 1606. The first kink 1614 can be a first bend were the wire 1604 transitions from the wire neck 1610 to the wire loop portion 1612. In some examples, a second kink 1616 or a subsequent bend can be located between the wire loop portion 1612 and the wire downward portion 1618. At the second kink 1616, the wire 1604 changes direction from the upward angle to a downward angle, descending toward the second connection point. The downward angle can align the wire 1604 to complete the bond at the second connection point on the wafer.

In this description, unless otherwise stated, “about,” “approximately” or “substantially” preceding a parameter means being within +/−10 percent of that parameter. Modifications are possible in the described embodiments and other embodiments are possible, within the scope of the claims.

What is claimed is:

1. A semiconductor package comprising:
a supporting structure; and
a die comprising a surface on which wire posts are located and coupled to die connection points, the wire posts being coupled using solder to the supporting structure.

2. The semiconductor package of claim 1, wherein the supporting structure is a lead frame that includes leads, and each wire post of the wire posts is coupled to one of the leads by the solder.

3. The semiconductor package of claim 1, wherein one or more wire posts of the wires posts is a ribbon wire post.

4. The semiconductor package of claim 1, wherein multiple wire posts of the wire posts are coupled to a respective die connection point of the die connection points and are bonded by the solder to the supporting structure.

5. The semiconductor package of claim 1, wherein the supporting structure is a substrate that includes substrate pads, and each wire post of the wire posts is coupled to one of the substrate pads by the solder.

6. The semiconductor package of claim 1, wherein the wire posts are made of a Copper material.

7. A method comprising:
bonding first and second end portions of a wire to a wafer;
forming a resist layer on a surface of the wafer to cover each of the first and second end portions while leaving a middle portion of the wire exposed;
grinding the middle portion of the wire to leave the first and second wire portions of the wire embedded within the resist layer to form wire posts; and
removing the resist layer to reveal the wire posts.

8. The method of claim 7, wherein the resist layer is a photoresist (PR) layer.

9. The method of claim 7, wherein the surface of the wafer is coated with a resist material to form the resist layer on the surface of the wafer.

10. The method of claim 9, further comprising exposing the resist layer to an ultraviolet (UV) light.

11. The method of claim 10, wherein the resist layer is a positive PR layer.

12. The method of claim 10, further comprising developing the resist layer to remove resist layer from the surface of the wafer to reveal the wire posts.

13. The method of claim 7, wherein the middle portion of the wire is grinded to a top surface of the resist layer in response to forming the resist layer.

14. The method of claim 7, wherein a height of the wire posts is based on a thickness of the resist layer.

15. The method of claim 7, further comprising cutting the wafer into dies, wherein the wire posts are located on a respective die of the dies.

16. The method of claim 15, further comprising forming the semiconductor package using the respective die and a support structure for the die.

17. The method of claim 16, wherein the support structure is a substrate.

18. The method of claim 16, wherein the support structure is a lead frame and the forming comprises:
positioning the respective die with respect to the lead frame so that each wire post on the respective die is coaxial with a respective lead of the lead frame;
reflowing solder to bond each wire post with the respective lead of the lead frame; and
encapsulating the die and the portion of the lead frame with the molding material.

19. A method for fabricating a semiconductor package, the method comprising:
forming wire posts on a surface of a wafer, the wire posts extending from a surface of the wafer;
cutting the wafer into dies, wherein the wire posts are formed on a die of the dies;
positioning the die with respect to a lead frame so that each wire post of the wire posts on the die is coaxial with a respective lead of the lead frame;
reflowing solder to bond each wire post with the respective lead of the lead frame; and
forming the semiconductor package by encapsulating the die and a portion of the lead frame with a molding material.

20. The method of claim 19, wherein the forming comprises:
bonding first and second end portions of a wire to the wafer;
forming a resist layer on a surface of the wafer to cover each of the first and second end portions while leaving a middle portion of the wire exposed;
grinding the middle portion of the wire to leave the first and second wire portions of the wire embedded within the resist layer to form the wire posts; and
removing the resist layer to reveal the wire posts.
